(19) United States
(12) Patent Application Publication
(10) Pub. No.: US 2017/0198386 A1
(43) Pub. Date: Jul. 13, 2017

(54) METHOD OF MAKING CONDUCTING CERAMIC GLASS WITH TEXTURE AND SMOOTHNESS

(71) Applicants: Ratnakar D. Vispute, Columbia, MD (US); Ashok Chaudhari, Briarcliff Manor, NY (US)

(72) Inventors: Ratnakar D. Vispute, Columbia, MD (US); Ashok Chaudhari, Briarcliff Manor, NY (US)

(73) Assignees: Blue Wave Semiconductors, Inc., Baltimore, MD (US); Solar-Tectic, LLC, Briarcliff Manor, NY (US)

(21) Appl. No.: 15/469,962

(22) Filed: Mar. 27, 2017

Related U.S. Application Data
(63) Continuation-in-part of application No. 14/663,067, filed on Mar. 19, 2015.
(60) Provisional application No. 61/955,543, filed on Mar. 19, 2014.

(51) Int. Cl. C23C 14/18; C30B 23/00; C23C 14/10; C03C 17/00; C23C 14/02

(52) U.S. Cl. CPC C23C 14/18; C03C 17/00; C23C 14/024; C23C 14/10; C30B 23/00

(57) ABSTRACT

A method for making ceramic glass that is textured, hard, transparent and conducting, for use in various electronic devices and displays, such as LEDs, solar cells, the covers of solar panels, CICs used in satellites, smartphones, and computer displays. The ceramic glass can also be used for window shields in automobiles, and in any other industries where anti-scratch glass is beneficial. The ceramic glass is composed of ultra-thin layers which reduces the cost of manufacturing, and provides advantageous properties such as smoothness for stringent electronic device fabrication requirements. The method includes depositing a crystalline MgO film on a glass substrate at a temperature below the softening point of the glass, depositing a metal thin-film one nanometer at a time on said MgO film on the glass substrate at a similar temperature while keeping the substrate heated, wherein said MgO film is less than 1 micron thick, and said metal thin-film is less than 20 nanometers thick, and introducing O₂ after each one nanometer layer of said metal thin film.

### PRIORITY AND RELATED APPLICATION

This application is a Continuation in Part of U.S. patent application Ser. No. 14/663,067, filed Mar. 19, 2015, entitled “Method of Making Ceramic Glass,” which claims priority to U.S. Provisional Patent Application Ser. No. 61/955,543, filed Mar. 19, 2014, entitled “Method of Making Sapphire Glass.” Both applications are hereby incorporated by reference their entirety.

### FIELD OF THE INVENTION

The present invention relates to covers for displays used in devices such as smartphones, smartwatches, and computers, and to substrates used in various electronic devices such as thin-film photovoltaic modules, Light Emitting Diodes (LEDs), and Field Effect Transistors (FETs).

### BACKGROUND OF THE INVENTION

Sapphire or “sapphire glass,” as it is sometimes called, is a ceramic that has many industrial applications, from watch covers to envelopes for use in high temperature lamps. It is also used in military applications. Covers used in many electronic devices today, such as displays, require not only transparency but hardness for anti-scratch capability. Sapphire, one of the hardest materials, is an ideal material to meet this need. Recently, sapphire or single crystalline Al₂O₃ has been referred to as “sapphire glass” which is a layman's term meant to highlight the fact that crystalline Al₂O₃ is transparent like glass. As a transparent material with a hardness only second to diamond, it has been claimed recently as an ideal material for display covers. But sapphire glass has in fact long been used in the semiconductor industry for various applications, along with other industries such as the watch industry, for just one example. The one and only drawback of sapphire, at least as far as scratch-resistance goes, has been cost. Recently there have been attempts to reduce the price of sapphire glass for use as display covers by GTAT and Apple Inc., that disclosed methods for making inexpensive sapphire glass. Apple has disclosed additional technology for sapphire glass covers in patent applications, as have other companies, such as Corning Inc. “Sapphire glass” should therefore be considered to include polycrystalline or nanocrystalline Al₂O₃ (not just single crystalline) given recent patent disclosures by Apple Inc.

Industrial sapphire is created by melting aluminum oxide (Al₂O₃) at 2040° C. and then encouraging crystal growth with a seed and careful control of the environment. Manufacturers have developed several unique methods for growth, with varying levels of resultant quality, size, and cost. The EFG or Stephanov methods allow the directed growth of shapes like ribbon, or even tubes, however there are many limitations to what can be done. The Czochralski, HEM, or Kiropolous methods allow the highest optical quality sapphire, but the result is a rod-like “blob” of crystal called a boule, that must be entirely machined into useable shapes and sizes. Traditionally sapphire glass has been manufactured by forming boules by either the Verneuil or Czochralski processes and then slicing the sapphire from these boules. However, this method requires very high temperatures and cutting and polishing the sapphire boules requires added time and process challenges. More to the point, when making sapphire glass for devices such as smartphones, or other small devices, sapphire ingot yield rates can be as low as below 50 percent. For these and other reasons, sapphire glass as it is currently produced is expensive and not economical. Alternatively, one can make sapphire glass by sintering Al₂O₃ powder in order to form small grain Al₂O₃ material. Crystalline Al₂O₃ made from small grains is known to be as hard and potentially even harder than single crystal sapphire or sapphire glass. However, this sintering process must also be performed at very high temperature, greater than 1200° C., and the process is also quite involved and so far has not been a commercially viable solution to making inexpensive sapphire glass. Recently, an invention for improving sapphire glass manufacturing was disclosed by Chaudhari et al (see U.S. 2014/0116329) and “Extremely highly textured MgO [111] crystalline films on soda-lime glass by e-beam” (Materials Letters 121 (2014) 47-49). These disclosures fail, however, to provide a method for making an enhanced quality ceramic (e.g. sapphire) layer on the crystalline MgO substrate.

Thus, a new method is disclosed here that will not only provide sapphire glass that is cost effective, simple, can take place at low temperatures (ideally 600 C or below), and also provide small grains for added hard, scratch-free, material, but can provide an enhanced, high quality ceramic layer such as sapphire. In accordance with one aspect of the present invention, the foregoing and other objects can be achieved by using the common electron beam (e-beam) evaporation process known in the trade, and depositing Magnesium Oxide (MgO) on a soda-lime glass substrate.

In accordance with another aspect of the present invention the foregoing and other objects can be achieved by using e-beam evaporating Al in an O₂ atmosphere to get a crystalline film on the MgO layer previously deposited. Specifically, this is done by evaporating Al and then adding O₂ so that Al reacts with O₂ on the surface of the MgO to form crystalline oxide.

In accordance with another aspect of the present invention the foregoing and other objects can be achieved by keeping Al on the MgO surface so it can spread on the surface to form a desired crystalline phase.

### BRIEF SUMMARY OF THE INVENTION

Ceramic glass, such as sapphire glass, is produced using e-beam to deposit Magnesium Oxide on a soda-lime glass substrate, followed by evaporation of Al in an O₂ atmosphere to get a crystalline film on the previously deposited MgO layer.

### BRIEF DESCRIPTION OF THE DRAWING

FIG. 1 shows TEM cross section of Al₂O₃ on highly textured MgO [111] layer. The MgO layer is on soda-lime glass, which cannot be seen here. Additionally, the Al₂O₃ film here is entirely amorphous (and therefore not the aim of the disclosed invention but demonstrates a step in that direction).

FIG. 2 is TEM diffraction pattern of highly textured MgO [111] film on soda-lime glass showing highly aligned, and textured, MgO.

FIG. 3 is profilometer data gathered from an embodiment of the present invention.

### DETAILED DESCRIPTION OF THE INVENTION

Transparent ceramics have many useful applications and consist of a number of materials. Sapphire (Al₂O₃), Spinel (MgAl₂O₄), AlON (Aluminium oxynitride spinel (Al₂₃O₂₇N₅)), and ZrO₂ are some of the most common and there are others. Today transparent ceramics are commonly made transparent by sintering. Here a novel method for making transparent ceramics from these materials is presented which replaces sintering with a process that has many advantages such as lower temperature, high texture, less material, simpler deposition, and potential for scalability.

In one embodiment of the invention, a thin layer of metal is deposited on a crystalline Magnesium Oxide (MgO) coated glass substrate followed by the introduction of oxygen (O₂). For example, in one embodiment, Al (aluminum) is deposited as a thin layer on the crystalline coated glass substrate followed by the introduction of O₂. The crystalline MgO coated substrate can be fabricated using the process disclosed by A. Chaudhari et al in “Extremely highly textured MgO[111] crystalline films on soda-lime glass by e-beam” and in U.S. patent application 2014/0245947 by Vispute and Seiser. Alternatively, the crystalline MgO can be deposited by any of the other techniques known in the art, such as Inclined Substrate Deposition (ISD) or Ion Beam Assisted Deposition (IBAD).

It should be noted that having two layers of material, for example Al₂O₃ and MgO, that are different, may have beneficial qualities. For example, the Al₂O₃ may be less likely to crack since the underlying layer is a different material and perhaps has a different orientation. This “weaving” effect may serve to strengthen the final cover material or film and have other beneficial effects.

The Al is deposited on the MgO/glass substrate at 550° C. and when O₂ is introduced a crystalline Al₂O₃ is formed. The Al is deposited 1 nm at a time, combined with O₂. If a thicker Al film were deposited, for example 500 nm, combined with O₂, then an Al₂O₃ film would form on the Al and it would be impossible to grow the crystalline Al₂O₃. The number of 1 nm Al with O₂ layers can vary according to the desired outcome. For example, a thicker layer may give better hardness value (Hv) as measured by Vickers or Knoop. On the other hand, a thinner layer may provide better transparency or real in-line transmission. Although small grains are preferable for increased hardness, according to the Hall-Petch relationship, it may be desirable in certain instances to increase the grain size. For example, larger grains are beneficial when depositing semiconductor thin-films such as silicon for solar cells, or GaN for LEDs. In this case, annealing the substrate after deposition of the Al₂O₃ layer may increase crystallinity and grain size.

It is known that Al₂O₃ has different phases, such as gamma and alpha. Moreover, it is known that each phase has certain attributes that can be desirable depending on the need. There are advantages and disadvantages to using alpha and gamma phases. In this invention, two different phases of Al₂O₃ are disclosed, alpha and gamma. For applications such as cover glass, hardness (Hv) is crucial for anti-scratch capability. In such applications, the sapphire (crystalline Al₂O₃ layer) may have a crystal structure that is gamma, since gamma phase Al₂O₃ is cubic. Moreover, another benefit of the cubic, gamma phase is that the non-cubic, alpha phase of Al₂O₃ has birefringence which reduces transparency. As it so happens, since the Al₂O₃ layer is deposited below 700° C. it is likely that the Al₂O₃ is cubic, because the phase of the Al₂O₃ is most likely gamma. With regard to alpha phase Al₂O₃, it is known that birefringence along the optic of c-axis of the alpha Al₂O₃ is eliminated. For alpha Al₂O₃ the c-axis is [006]. Finally anisotropic single crystal materials exhibit some properties such as thermal expansion and hardness which vary significantly by orientation. For example, sapphire with crystal orientation perpendicular to the c-axis is harder than orientation parallel to the c-axis. And c-axis sapphire is harder than other axes in Al₂O₃, such as r, n, or a.

Thus in one embodiment there is deposition of a gamma phase of Al₂O₃ and in another embodiment an alpha phase of Al₂O₃, and both embodiments are deposited heteroepitaxially on a crystalline MgO buffer layer on soda-lime glass. Each phase of Al₂O₃ is deposited separately, and can be chosen depending on the desired outcome.

Upon completion of the deposition process, polishing may or may not be required depending on the use. If the sapphire glass is going to be used for display covers, for example, it is unlikely that it needs polishing which would be an additional cost-savings advantage over current sapphire manufacturing techniques. If the sapphire glass is going to be used as a substrate for additional device fabrication on which layers will be deposited, then some polishing may be beneficial. If the sapphire glass is, for example, polycrystalline then crystallographic orientations being exposed on the surface potentially make a polishing operation difficult to achieve a quality surface as the different crystal planes of sapphire polish at different rates. If the sapphire glass is highly textured, and the crystal orientations have more or less the same planes, then polishing may be easier. In this case more time and money would be saved.

Finally, highly textured ceramic layers as discussed here, can serve as substrates on which to deposit highly textured heteroepitaxial semiconductor films such as silicon which due to the aligned grains can have advantageous light trapping and reflection control helpful in the case of solar cell devices (see Campbell et al, “Light trapping and reflection control in solar cells using tilted crystallographic surface textures,” 1993). The textured ceramics discussed here may have the same or similar light trapping and reflection properties.

### EXAMPLE 1

E-beam evaporation technique was used for the growth of sapphire glass. The evaporator consists of a stainless steel high vacuum chamber capable of reaching 10E-7 Torr with the help of a cryopump. Initial rough vacuum up to 10-3 Torr was achieved with a mechanical dry pump. Prior to vacuuming the chamber, batches of initial glass substrates were loaded on a substrate heater that is capable of controlling temperature of the substrates while growing the MgO buffer layer and sapphire layer in reactive deposition mode. A typical buffer layer of MgO was grown from stoichiometric MgO source material. The presence of background pressure of O₂ (˜10E-4 Torr using O₂ flow need valve)) helps high quality stoichiometric MgO depositions. Substrate temperature was controlled from 300 C to 650 C temperature range to control the preferred orientation of the MgO films. Required growth temperature was set using a substrate heater with a typical ramp rate ranging from 15 C/min to 45 C/min. At this stage the system is ready for deposition of the first layer that is MgO. E-beam parameters such as high voltage and emission current were set so that the appropriate evaporation rate of MgO can be achieved. The high voltage (HV approximately 8 KV) for electron beam was setup through potentiometer of the ebeam evaporator system. A good range for setting the bias for Telemark sources is between 17 to 20 A. The electron beam sweep pattern settings can also be judged and finalized without affecting the material. The ebeam system also has joystick that can directly control the e-beam output position, allowing the precondition of the material manually. Once high voltage and emission current is set with desirable evaporation rate of MgO, deposition was conducted for 1 to 2 hrs depending upon the film thickness requirement. Studies show varied film thickness of MgO films from a few microns to 6 microns is possible. After MgO deposition, a high purity aluminum (99.999) source was switched for deposition. Initially, the Al source was heated by ebeam to melt the source and the ebeam was adjusted for evaporation of aluminum. Partial pressure was adjusted from 10-4 Torr to 10-6 Torr in order to control reaction of the Al with O₂ on the substrate. Note that the arrival rate of O₂ is adjusted in a way that Al surface mobility can be as high as possible to allow surface migration and then reaction with oxygen so that crystalline properties, grain size, surface smoothness, optical transparency, and interface reaction can be controlled. Thus optimization of aluminum oxide (Al₂O₃) growth includes arrival rates of oxygen background reactive gas atoms and ebeam evaporated aluminum in such a way that aluminum has optimum surface migration for crystallinity and grain size control and reaction with oxygen to form crystalline sapphire (Al₂O₃) or sapphire glass.

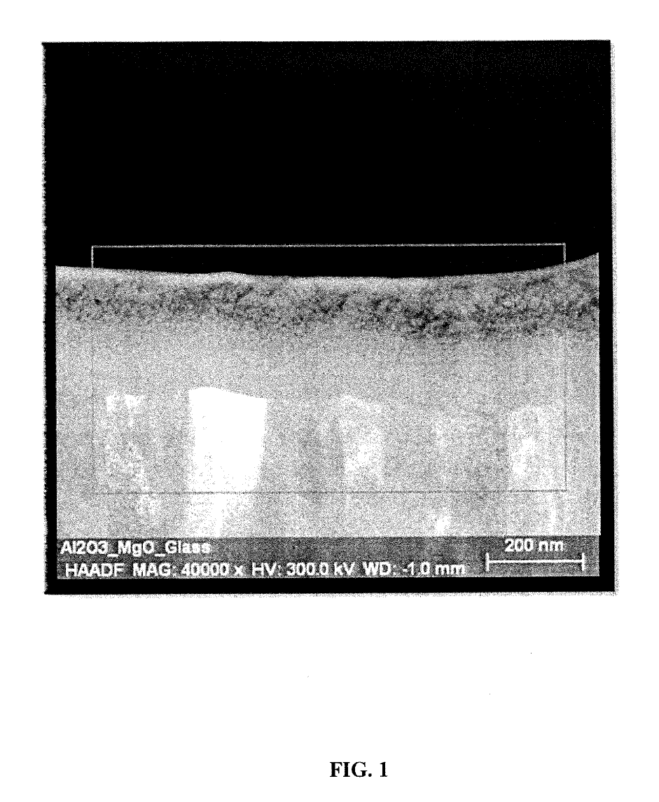

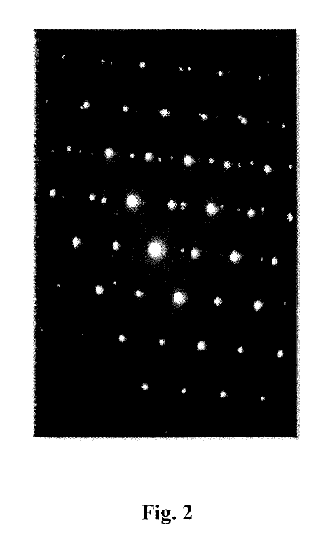

FIG. 1 shows TEM cross section of Al₂O₃ on highly textured MgO [111] layer. The MgO layer is on soda-lime glass, which cannot be seen here. Additionally, the Al₂O₃ film here is entirely amorphous (and therefore not the result of the inventive process, but is a step toward proof in conception). FIG. 2 shows TEM diffraction pattern of highly textured MgO [111] film on soda-lime glass showing highly aligned, and textured, MgO.

### EXAMPLE 2

The same process as in example 1 can be used to grow Zirconium Oxide (ZrO2).

E-beam evaporation technique is used for the growth of zirconium glass. The evaporator consists of a stainless steel high vacuum chamber capable of reaching 10E-7 Torr with the help of a cryopump. Initial rough vacuum up to 10-3 Torr is achieved with a mechanical dry pump. Prior to vacuuming the chamber, batches of initial glass substrates are loaded on a substrate heater that is capable of controlling temperature of the substrates while growing the MgO buffer layer and sapphire layer in reactive deposition mode. A typical buffer layer of MgO was grown from stoichiometric MgO source material. The presence of background pressure of O₂ (˜10E-4 Torr using O₂ flow need valve)) helps high quality stoichiometric MgO depositions. Substrate temperature was controlled from 300 C to 650 C temperature range to control the preferred orientation of the MgO films. Required growth temperature is set using a substrate heater with a typical ramp rate ranging from 15 C/min to 45 C/min. At this state the system is ready for deposition of the first layer that is MgO. E-beam parameters such as high voltage and emission current are set so that the appropriate evaporation rate of MgO can be achieved. The high voltage (HV approximately 8 KV) for electron beam is setup through potentiometer of the ebeam evaporator system. A range for setting the bias for Telemark sources may be between 17 to 20 A. The electron beam sweep pattern settings can also be judged and finalized without affecting the material. The ebeam system also has a joystick that can directly control the e-beam output position, allowing the precondition of the material manually. Once high voltage and emission current is set with desirable evaporation rate of MgO, deposition is conducted for 1 to 2 hrs depending upon the film thickness requirement. Studies show varied film thickness of MgO films from a few microns to 6 microns is possible. After MgO deposition, high purity zirconium (99.999) source is switched for deposition. Initially, the Zr source was heated by ebeam to melt the source and the ebeam is adjusted for evaporation of zirconium. Partial pressure was adjusted from 10-4 Torr to 10-6 Torr in order to control reaction of the Zr with O₂ on the substrate. Note that the arrival rate of O₂ is adjusted in a way that Zr surface mobility can be as high as possible to allow surface migration and then reaction with oxygen so that crystalline properties, grain size, surface smoothness, optical transparency, and interface reaction can be controlled. Thus optimization of zirconium oxide (ZrO₂) growth includes arrival rates of oxygen background reactive gas atoms and ebeam evaporated aluminum in such a way that Zr has optimum surface migration for crystallinity and grain size control and reaction with oxygen to form crystalline zirconium (ZrO₂).

### EXAMPLE 3

The same process as in example 1 can be used to grow silicon oxide (SiO₂).

E-beam evaporation technique was used for the growth of silicon oxide ceramic. The evaporator consists of a stainless steel high vacuum chamber capable of reaching 10E-7 Torr with the help of a cryopump. Initial rough vacuum up to 10-3 Torr is achieved with a mechanical dry pump. Prior to vacuuming the chamber, batches of initial glass substrates are loaded on a substrate heater that is capable of controlling temperature of the substrates while growing the MgO buffer layer and sapphire layer in reactive deposition mode. A typical buffer layer of MgO is grown from stoichiometric MgO source material. The presence of background pressure of O₂ (˜10E-4 Torr using O₂ flow need valve)) helps high quality stoichiometric MgO depositions. Substrate temperature is controlled from 300 C to 650 C temperature range to control the preferred orientation of the MgO films. Required growth temperature was set using a substrate heater with a typical ramp rate ranging from 15 C/min to 45 C/min. At this state the system is ready for deposition of the first layer that is MgO. E-beam parameters such as high voltage and emission current are set so that the appropriate evaporation rate of MgO can be achieved. The high voltage (HV approximately 8 KV) for electron beam is setup through potentiometer of the ebeam evaporator system. A good range for setting the bias for Telemark sources is between 17 to 20 A. The electron beam sweep pattern settings can also be judged and finalized without affecting the material. The ebeam system also has joystick that can directly control the e-beam output position, allowing the precondition of the material manually. Once high voltage and emission current is set with desirable evaporation rate of MgO, deposition was conducted for 1 to 2 hrs depending upon the film thickness requirement. Studies show varied film thickness of MgO films from a few microns to 6 microns is possible. After MgO deposition, high purity Si (99.999) source was switched for deposition. Initially, the Si source was heated by ebeam to melt the source and the ebeam is adjusted for evaporation of Si. Partial pressure was adjusted from 10-4 Torr to 10-6 Torr in order to control reaction of the Si with O₂ on the substrate. Note that the arrival rate of O₂ is adjusted in a way that Si surface mobility can be as high as possible to allow surface migration and then reaction with oxygen so that crystalline properties, grain size, surface smoothness, optical transparency, and interface reaction can be controlled. Thus optimization of Si oxide (SiO₂) growth includes arrival rates of oxygen background reactive gas atoms and ebeam evaporated silicon in such a way that silicon has optimum surface migration for crystallinity and grain size control and reaction with oxygen to form crystalline silicon oxide (SiO₂).

### EXAMPLE 4

The same process as in example 1 can be used to grow a nitride, such as titanium nitride (TiN) ceramic.

E-beam evaporation technique is used for the growth of TiN. The evaporator consists of a stainless steel high vacuum chamber capable of reaching 10E-7 Torr with the help of a cryopump. Initial rough vacuum up to 10-3 Torr is achieved with a mechanical dry pump. Prior to vacuuming the chamber, batches of initial glass substrates are loaded on a substrate heater that is capable of controlling temperature of the substrates while growing the MgO buffer layer and sapphire layer in reactive deposition mode. A typical buffer layer of MgO is grown from stoichiometric MgO source material. The presence of background pressure of O₂ (—10E-4 Torr using O₂ flow need valve)) helps high quality stoichiometric MgO depositions. Substrate temperature is controlled from 300 C to 650 C temperature range to control the preferred orientation of the MgO films. Required growth temperature is set using a substrate heater with a typical ramp rate ranging from 15 C/min to 45 C/min. At this state the system is ready for deposition of the first layer that is MgO. E-beam parameters such as high voltage and emission current are set so that the appropriate evaporation rate of MgO can be achieved. The high voltage (HV approximately 8 KV) for electron beam was setup through potentiometer of the ebeam evaporator system. A good range for setting the bias for Telemark sources is between 17 to 20 A. The electron beam sweep pattern settings can also be judged and finalized without affecting the material. The ebeam system also has joystick that can directly control the e-beam output position, allowing the precondition of the material manually. Once high voltage and emission current is set with desirable evaporation rate of MgO, deposition is conducted for 1 to 2 hrs depending upon the film thickness requirement. Studies show varied film thickness of MgO films from a few microns to 6 microns is possible. After MgO deposition, high purity titanium (99.999) source is switched for deposition. Initially, the Ti source is heated by ebeam to melt the source and the ebeam is adjusted for evaporation of titanium. Partial pressure is adjusted from 10-4 Torr to 10-6 Torr in order to control reaction of the Ti with O₂ on the substrate. Note that the arrival rate of O₂ is adjusted in a way that Ti surface mobility can be as high as possible to allow surface migration and then reaction with oxygen so that crystalline properties, grain size, surface smoothness, optical transparency, and interface reaction can be controlled. Thus optimization of Ti nitride (TiN) growth includes arrival rates of oxygen background reactive gas atoms and ebeam evaporated Ti in such a way that Ti has optimum surface migration for crystallinity and grain size control and reaction with oxygen to form crystalline titanium nitride (TiN).

In the preceding samples further annealing, for example for 1 or 2 hours, with Ar, or O₂, may be desirable.

When designing glass for cover purposes, reflectivity is an issue that needs to be addressed. The greater the reflectivity the lower the transmission. Therefore, it can be advantageous to add an anti-reflection coating to the Al₂O₃, or ceramic, layer.

As discussed above, the thickness or thinness of the Al₂O₃ film and MgO film on glass can be adjusted depending on the desired outcome. It can be for example more economical to make thinner layers. For example, only 20 nm of Al₂O₃ from Al+O₂ deposited 1 nanometer at a time on only 1 μm MgO [111] textured film on quartz at 800° C. still achieved a MOHS 8+, which is very close to single crystal sapphire having a MOHS 9. MgO film having a thickness of 1 micron thick or less and the metal thin-film having a thickness of 20 nanometers or less can be preferable. Further reduction in film thickness of MgO could save additional time and cost without compromising hardness or transparency. On the other hand, an increase in Al₂O₃ film thickness to greater than 20 nm—say 100 nm—might increase hardness; or a decrease of Al₂O₃ film thickness yet further to 10 nm for example might lead to even better quality films—single crystal or harder or more transparent or smoother. Thicker films may mean rougher films. The combination of MgO [111] textured film and Al+O₂ gives such that transparency is possible even with crystallinity—MgO [111] leads to single crystal-like Al₂O₃. In general, the grain size of the materials should be less than 500 nm (the wavelength of visible light is 400 nm-700 nm) so the material does not scatter light and make it translucent. However, such grains can be considered ‘large’ relative to the film thickness. The present invention makes use of MgO and Al₂O₃, each serving different purposes. When used together, the MgO can serve as a protective layer on glass plasma display panels, while the Al₂O₃ provides the anti-scratch top layer. Thus, the ceramic glass in the present invention solves two problems at once when used with plasma display panels: protection and anti-scratch.

In another embodiment of the invention, electrically conducting glass can be made following the same process but this time depositing conducting layers of nitrides such as TiN or ZrN on the MgO/glass substrate. These layers are not only conducting and hard (MOHS 8-9), but also transparent, and therefore can have various applications beyond anti-scratch coatings, such as window shield glass in automobiles which require conducting layers for heating, or substrates for solar cells and other than electronic devices which require conducting back contacts or electrodes. The ability of the Nitride films to conduct is improved by the texture of the films induced by the MgO [111] film, and these films have an advantage over the Al₂O₃ films in this invention in that not only are they hard (possibly harder), transparent and textured, but they are also conducting.

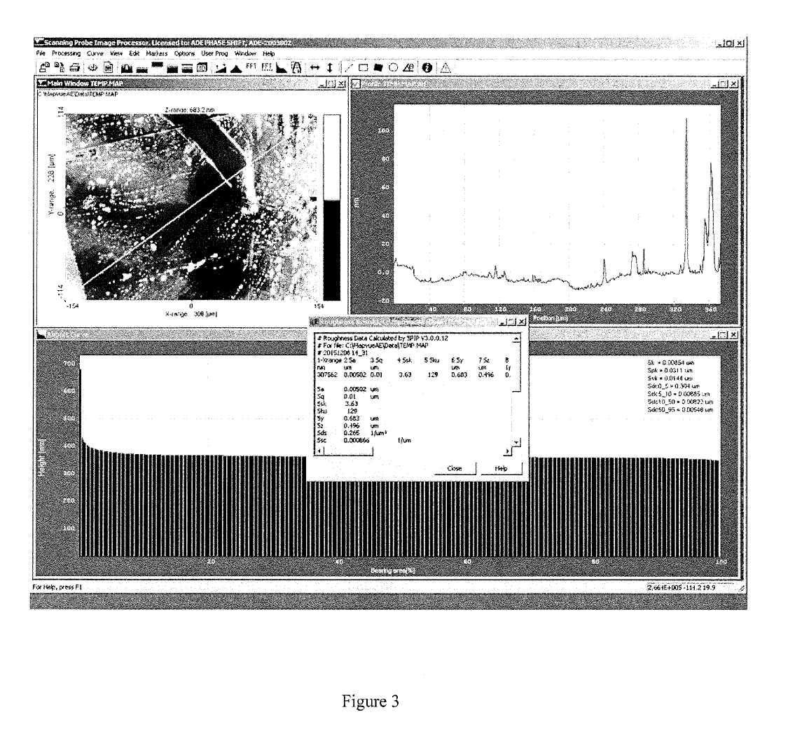

The ceramic glass in one embodiment of the present invention is composed of smooth layers. For example, the MgO [111] film when deposited at 350° C. had an average roughness of 5 nm and the RMS is about 10 nm. MgO having an average roughness of 5 nm or less, and an RMS of 10 nm or less is preferred in an embodiment of the invention. FIG. 3 shows the profilometer data of crystalline MgO film on soda-lime glass deposited at 350° C. Sa is the average roughness: 5 nm, and the RMS is about 10 nm. The ceramic top layer, e.g. sapphire, has a roughness average of 3 nm or less, such as 1 nm. Smoothness is advantageous for electronic device fabrication requirements.

The ceramic glass in one embodiment of the present invention can be used as substrates in various electronic devices such as displays, LEDs, solar cells, and in the covers of solar panels, smartphones, displays, windows in automobiles, etc. It can also be used for the cover glass used in CICs in solar panels for satellites. A CIC is an assembly comprised of a solar cell+interconnects+cover glass+bypass Diode. The cover glass (in some cases around 75 microns) protects the cell from cosmic radiation, i.e. electron and proton radiation. Sapphire is a particularly effective material for this protective purpose. And in one embodiment of the present invention, the sapphire glass is composed of ultra-thin layers which reduce the cost of manufacturing CICs.

### EXAMPLE 5

Electron-beam evaporation technique was used for the growth of sapphire glass with varying thicknesses. The evaporator consists of a stainless steel high vacuum chamber capable of reaching 10E-7 Torr with the help of a cryopump. Initial rough vacuum up to 10-3 Torr was achieved with a mechanical dry pump. Prior to vacuuming the chamber, batches of initial glass substrates were loaded on a substrate heater that is capable of controlling temperature of the substrates while growing the MgO buffer layer and sapphire layer in reactive deposition mode. A typical buffer layer of MgO was grown from stoichiometric MgO source material. The presence of background pressure of O₂ (˜10E-4 Torr using O₂ flow need valve) helps high quality stoichiometric MgO depositions. Substrate temperature was controlled from 300° C. to 650° C. temperature range to control the preferred orientation of the MgO films. Lower temperature depositions, for example 350° C., may lead to larger grain sizes which can be beneficial. Required growth temperature was set using a substrate heater with a typical ramp rate ranging from 15° C./min to 45° C./min. At this stage the system is ready for deposition of the first layer that is MgO. E-beam parameters such as high voltage and emission current were set so that the appropriate evaporation rate of MgO can be achieved. The high voltage (HV approximately 8KV) for electron beam was setup through potentiometer of the e-beam evaporator system. A good range for setting the bias for Telemark sources is between 17 to 20 A. The electron beam sweep pattern settings can also be judged and finalized without affecting the material. The e-beam system also has joystick that can directly control the e-beam output position, allowing the precondition of the material manually. Once high voltage and emission current is set with desirable evaporation rate of MgO, deposition was conducted for 1 to 2 hrs depending upon the film thickness requirement. In this case a 500 nm thin MgO film was grown to save time, energy and cost. After MgO deposition, a high purity aluminum (99.999) source was switched for deposition. Initially, the Al source was heated by e-beam to melt the source and the e-beam was adjusted for evaporation of aluminum. Partial pressure was adjusted from 10-4 Torr to 10-6 Torr in order to control reaction of the Al with O₂ on the substrate. Note that the arrival rate of O₂ is adjusted in a way that Al surface mobility can be as high as possible to allow surface migration and then reaction with oxygen so that crystalline properties, grain size, surface smoothness, optical transparency, and interface reaction can be controlled. Thus optimization of aluminum oxide (Al₂O₃) growth includes arrival rates of oxygen background reactive gas atoms and e-beam evaporated aluminum in such a way that aluminum has optimum surface migration for crystallinity and grain size control and reaction with oxygen to form crystalline sapphire (Al₂O₃) or sapphire glass. In this example, a very thin Al₂O₃ film of only 20 nm is deposited. Any residual or intentional doping of the Al₂O₃ film with MgO from the MgO film helps with density and therefore porosity.

### EXAMPLE 6

The same process as in example 5 can be used to grow a conducting nitride ceramic, such as ZrN, which is an almost perfect match with MgO [111] and is hard (MOHS 8+).

E-beam evaporation technique is used for the growth of ZrN. The evaporator consists of a stainless steel high vacuum chamber capable of reaching 10E-7 Torr with the help of a cryopump. Initial rough vacuum up to 10-3 Torr is achieved with a mechanical dry pump. Prior to vacuuming the chamber, batches of initial glass substrates are loaded on a substrate heater that is capable of controlling temperature of the substrates while growing the MgO buffer layer and sapphire layer in reactive deposition mode. A typical buffer layer of MgO is grown from stoichiometric MgO source material. The presence of background pressure of O₂ (˜10E-4 Torr using O₂ flow need valve)) helps high quality stoichiometric MgO depositions. Substrate temperature is controlled from 300° C. to 650° C. temperature range to control the preferred orientation of the MgO films. Required growth temperature is set using a substrate heater with a typical ramp rate ranging from 15° C./min to 45° C./min. At this state the system is ready for deposition of the first layer that is MgO. E-beam parameters such as high voltage and emission current are set so that the appropriate evaporation rate of MgO can be achieved. The high voltage (HV approximately 8 KV) for electron beam was setup through potentiometer of the e-beam evaporator system. A good range for setting the bias for Telemark sources is between 17 to 20 A. The electron beam sweep pattern settings can also be judged and finalized without affecting the material. The e-beam system also has joystick that can directly control the e-beam output position, allowing the precondition of the material manually. Once high voltage and emission current is set with desirable evaporation rate of MgO, deposition is conducted for 1 to 2 hrs depending upon the film thickness requirement. Studies show varied film thickness of MgO films from a few microns to 6 microns. After MgO deposition, high purity zirconium (99.999) source is switched for deposition. Initially, the Zi source is heated by e-beam to melt the source and the e-beam is adjusted for evaporation of titanium. Partial pressure is adjusted from 10-4 Torr to 10-6 Torr in order to control reaction of the Zi with O₂ on the substrate. Note that the arrival rate of O₂ is adjusted in a way that Zi surface mobility can be as high as possible to allow surface migration and then reaction with oxygen so that crystalline properties, grain size, surface smoothness, optical transparency, and interface reaction can be controlled. Thus optimization of Zr nitride (ZrN) growth includes arrival rates of oxygen background reactive gas atoms and e-beam evaporated Zi in such a way that Zi has optimum surface migration for crystallinity and grain size control and reaction with oxygen to form crystalline zirconium nitride (ZrN).

In the preceding samples further annealing, for example for 1 or 2 hours, with Ar, or O₂, may be desirable.

In the present invention, the terms ‘textured’ and ‘large grain’ have the following meaning: ‘textured’ means that the crystals in the film have preferential orientation either out-of-plane or in-plane or both. For example, in the present invention the films could be highly oriented out-of-plane, along the c-axis. By ‘large grain’ it is meant that the grain size is greater than or equal to the film thickness.

While the present invention has been described in conjunction with specific embodiments, those of normal skill in the art will appreciate the modifications and variations can be made without departing from the scope and the spirit of the present invention. Such modifications and variations are envisioned to be within the scope of the appended claims.

1) A method of making ceramic glass comprising steps of:
depositing a crystalline MgO film on a glass substrate at a temperature below the softening point of the glass;
depositing a metal thin-film one nanometer at a time on said MgO film on the glass substrate at a similar temperature, while keeping the substrate heated, wherein said MgO film is less than 1 micron thick, and said metal thin-film is less than 20 nanometers thick, and
introducing O₂ after each one nanometer layer of said metal thin film.

2) The method of claim 1, wherein said MgO film has an average roughness of 5 nm or less, and a RMS of 10 nm or less.

3) The method of claim 1, wherein said ceramic glass is conducting.

4) The method of claim 1, wherein said ceramic glass is used in the covers of solar panels.

5) The method of claim 1, wherein said ceramic glass is used in display covers.

6) The method of claim 1, wherein said ceramic glass is used as the substrate for LEDs and OLEDs.

7) The method of claim 1, wherein said ceramic glass is sapphire glass.

8) The method of claim 7, wherein said sapphire glass is used in CICs.

9) The method of claim 1, wherein said ceramic glass has a roughness of 3 nm or less.

10) The method of claim 1, wherein said ceramic glass serves both as a protection layer on plasma displays panels and as anti-scratch layer for the same.

11) A ceramic glass assembly comprised of a:
crystalline MgO film on glass having a thickness of less than 1 micron, and
a ceramic layer on top of said MgO film having a thickness of less than 20 nm.
